(19) United States
(12) Patent Application Publication
(10) Pub. No.: US 2025/0261382 A1
(43) Pub. Date: Aug. 14, 2025

(54) INDUCTOR STRUCTURE INTEGRATED IN SEMICONDUCTOR DEVICE

(71) Applicant: GlobalFoundries U.S. Inc., Malta, NY (US)

(72) Inventors: INDRAJIT DAS, Bangalore (IN); VENKATA NARAYANA RAO VANUKURU, Bangalore (IN); HARI KISHORE KAKARA, Bangalore (IN)

(21) Appl. No.: 18/442,069

(22) Filed: Feb. 14, 2024

(51) Int. Cl. H01L 23/522; H01L 25/065; H01L 29/73

(52) U.S. Cl. CPC H10D 1/20; H01L 23/5226; H01L 25/0657; H10D 10/00; H01L 2225/06548

(57) ABSTRACT

The disclosed subject matter relates generally to an inductor structure integrated in a semiconductor device formed from bonded wafers, in which the semiconductor device has a three-dimensional inductor structure aligned vertically between two integrated circuit (IC) components. The inductor structure has a first metal level and a second metal level, the first metal level being in a different wafer from the second metal level.

### FIELD OF THE INVENTION

The disclosed subject matter relates generally to an inductor structure integrated into a semiconductor device. More particularly, the present disclosure relates to a semiconductor device preferably formed from bonded wafers, in which the semiconductor device has a three-dimensional inductor structure aligned vertically between two integrated circuit components.

### BACKGROUND

Inductors are components in an electrical circuit along with resistors, capacitors, and transistors. An inductor may typically have a structure where a conductor is wound many times in a coil, screw, or spiral form. With an increased demand for communication electronic devices, semiconductor devices or integrated circuit (IC) devices may, for example, include voltage-controlled oscillators (VCO), low noise amplifiers (LNA), tuned radio receiver circuits, or power amplifiers (PA). Each of these tuned radio receiver circuits, VCO, LNA, and PA circuits may require inductor components in their circuit designs.

Furthermore, semiconductor devices and IC devices are typically manufactured on a single semiconductor wafer. The dies of the wafer may be processed and packaged with other semiconductor devices or dies at the wafer level, and various technologies and applications have been developed for wafer level packaging. Integration of multiple semiconductor devices has become a challenge in the field with the need for chips with smaller footprints and a reduction of wasted board space on printed circuit boards.

### SUMMARY

In an aspect of the present disclosure, there is provided a semiconductor device having a first semiconductor layer, a second semiconductor layer, an inductor structure vertically between the first semiconductor layer and the second semiconductor layer, the inductor structure having a first metal level and a second metal level above the first metal level, the first metal level and the second metal level each comprises at least one turn about a vertical axis, a dielectric region vertically between the first and second metal levels of the inductor structure, a first interconnect via in the dielectric region, the first interconnect via has a height, and the first interconnect via electrically contacts the first metal level of the inductor structure, and a second interconnect via in the dielectric region, the second interconnect via directly contacts the first interconnect via, the second interconnect via has a height different from the height of the first interconnect via, and the second interconnect via electrically contacts the second metal level of the inductor structure.

In another aspect of the present disclosure, there is provided a semiconductor device having a first transistor on a first semiconductor layer, the first transistor has a gate structure, a second transistor on a second semiconductor layer, the second transistor has a gate structure, an inductor structure vertically between the first transistor and the second transistor, the inductor structure having a center region, a first metal level, and a second metal level above the first metal level, the first metal level is electrically connected to the first transistor, the second metal level is electrically connected to the second transistor, the first metal level and the second metal level each comprises at least one turn that spiral about the center region of the inductor structure, in which the gate structure of the first transistor and the gate structure of the second transistor are vertically aligned with the center region of the inductor structure, a dielectric region vertically between the first and second metal levels of the inductor structure, a first interconnect via in the dielectric region, the first interconnect via electrically contacts the first metal level of the inductor structure, and a second interconnect via in the dielectric region, the second interconnect via directly contacts the first interconnect via, and the second interconnect via electrically contacts the second metal level of the inductor structure.

In yet another aspect of the present disclosure, there is provided a semiconductor device having a first semiconductor die having a first interlayer dielectric level, a first integrated circuit (IC) component in the first semiconductor die, a second semiconductor die vertically above the first semiconductor die, the second semiconductor die having a second interlayer dielectric level, the second interlayer dielectric level directly contacts the first interlayer dielectric level, and the second interlayer dielectric level has a different thickness from the first interlayer dielectric level, a second IC component in the second semiconductor die, an inductor structure vertically between the first IC component and the second IC component, the inductor structure having a first metal level in the first semiconductor die and a second metal level in the second semiconductor die, the first metal level is electrically connected to the first IC component, and the second metal level is electrically connected to the second IC component, the first metal level and the second metal level each comprises at least one turn about a vertical axis, a first interconnect via in the first interlayer dielectric level, the first interconnect via electrically contacts the first metal level of the inductor structure, and a second interconnect via in the second interlayer dielectric level, the second interconnect via directly contacts the first interconnect via, and the second interconnect via electrically contacts the second metal level of the inductor structure.

### BRIEF DESCRIPTION OF THE DRAWINGS

The present disclosure may be understood by reference to the following description taken in conjunction with the accompanying drawings.

For simplicity and clarity of illustration, the drawings illustrate the general manner of construction, and certain descriptions and details of features and techniques may be omitted to avoid unnecessarily obscuring the discussion of the described embodiments of the present disclosure. Additionally, elements in the drawings are not necessarily drawn to scale. For example, the dimensions of some of the elements in the drawings may be exaggerated relative to other elements to help improve understanding of embodiments of the present disclosure. The same reference numerals in different drawings denote the same elements, while similar reference numerals may, but do not necessarily, denote similar elements.

FIG. 1 is a perspective schematic view of an example of a semiconductor device having an inductor structure vertically between a first IC component and a second IC component.

FIG. 2A is a cross-sectional view of the example semiconductor device along a vertical plane containing a line AA shown in FIG. 1.

FIG. 2B is a cross-sectional view of the example semiconductor device along a vertical plane containing a line BB shown in FIG. 1.

FIG. 3A and FIG. 3B are enlarged cross-sectional views of a first interconnect via electrically contacting a first metal level of the inductor structure and a second interconnect via electrically contacting a second metal level of the inductor structure in the example semiconductor device shown in FIG. 2B.

FIG. 4 is a top-down view of the first metal level of the inductor structure in the example semiconductor device shown in FIG. 1.

FIG. 5 is a top-down view of the second metal level of the inductor structure in the example semiconductor device shown in FIG. 1.

### DETAILED DESCRIPTION

Various illustrative embodiments of the present disclosure are described below. The embodiments disclosed herein are exemplary and not intended to be exhaustive or limiting to the present disclosure.

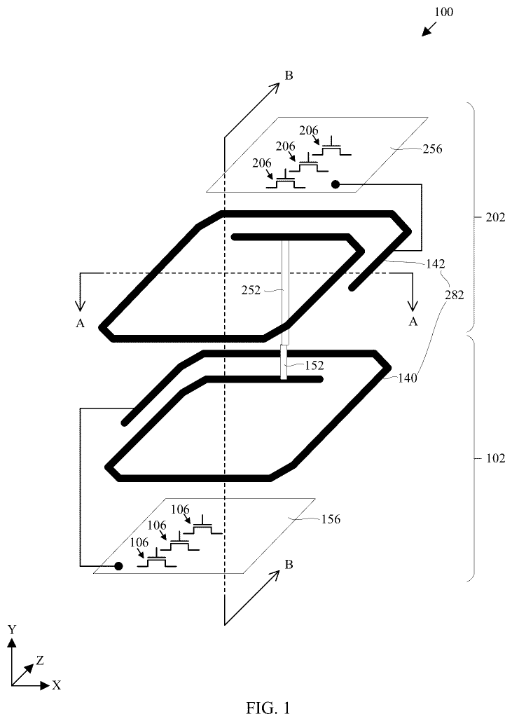

FIG. 1 illustrates an example of a semiconductor device 100 having an inductor structure 282 vertically between a first IC component 156 and a second IC component 256. Line AA is a section line along a vertical plane parallel to the YX plane while line BB is a section line along a vertical plane parallel to the YZ plane. Referring to FIG. 1, the semiconductor device 100 may include a first semiconductor die 102 and a second semiconductor die 202. The semiconductor device 100 may be formed using a wafer to wafer bonding process (e.g., hybrid bonding or direct bonding), a wafer to die bonding process, a die to wafer bonding process, or a die to die bonding process. The subsequently bonded wafers (or bonded wafer and die) may be diced to form the bonded semiconductor dies 102 and 202. The first semiconductor die 102 may include the first IC component 156 while the second semiconductor die 202 may include the second IC component 256. The first IC component 156 may include a first plurality of transistors 106 and the second IC component 256 may include a second plurality of transistors 206. The pluralities of transistors 106, 206 may be configured as common source device and common gate device. The IC components 156, 256 may refer to components in the semiconductor device having circuitry configured for an amplifier (e.g., power amplifier, low noise amplifier, voltage amplifier, transconductance amplifier, etc.). As shown in FIG. 1, the first plurality of transistors 106 may have at least one transistor connected to the first metal level 140 of the inductor structure 282. The second plurality of transistors 206 may have at least one transistor connected to the second metal level 142 of the inductor structure 282.

Although not shown in the accompanying drawings, it should be noted that the scope of this disclosure also includes examples where the inductor structure 282 includes one or more metal levels in addition to the first and second metal levels 140, 142 illustrated in FIG. 1. In other words, the inductor structure 282 may include three or more metal levels. The three or more metal levels may have at least one metal level in the first semiconductor die 102 and at least one metal level in the second semiconductor die 202. For example, the inductor structure 282 may have three metal levels, the first semiconductor die 102 may include two metal levels of the inductor structure 282 while the second semiconductor die 202 may include one metal level of the inductor structure 282. In another example, the inductor structure 282 may have four metal levels, the first semiconductor die 102 and the second semiconductor die 102 may each include two metal levels of the inductor structure. The number of metal levels of the inductor structure 282 in the first semiconductor die 102 may be either the same as or different from the number of metal levels of the inductor structure 282 in the second semiconductor die 202.

The inductor structure 282 may include a first metal level 140 and a second metal level 142. The first metal level 140 may be in the first semiconductor die 102 and may be electrically connected to the first IC component 156, for example, by various interconnect features (as illustrated in subsequent drawings). The second metal level 142 may be in the second semiconductor die 202 and may be electrically connected to the second IC component 256, for example, by various interconnect features (as illustrated in subsequent drawings). The first and second metal levels 140 and 142 may each include at least one turn about a vertical axis (e.g., Y-axis). The at least one turn in the first and second metal levels 140 and 142 may each include a metal line that extends along a horizontal plane (or a plane that the vertical axis is normal to). As used herein, the term “turn” in the metal levels 140, 142 of the inductor structure 282 may refer to a metal line, or a part thereof, that makes at least one bend around the vertical axis. The first IC component 156, the second IC component 256, the first metal level 140 of the inductor structure 282, and the second metal level 142 of the inductor structure 282 may be aligned vertically along the vertical axis. The first semiconductor die 102 may include a first interconnect via 152. The first interconnect via 152 may electrically contact or directly contact the first metal level 140. The second semiconductor die 202 may include a second interconnect via 252. The second interconnect via 252 may electrically contact or directly contact the second metal level 142. The second interconnect via 252 may have a different height from the first interconnect via 152. The second interconnect via 252 may directly contact the first interconnect via 152.

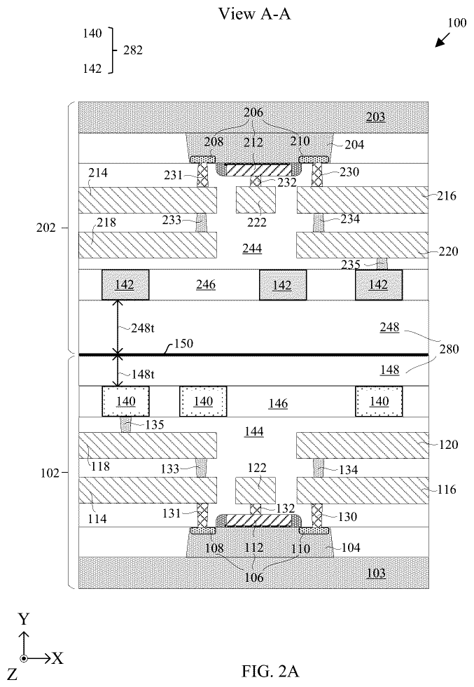

Referring to FIG. 2A and FIG. 2B, the semiconductor device 100 may include a first semiconductor layer 104, a second semiconductor layer 204, and an inductor structure 282 vertically between the first semiconductor layer 104and the second semiconductor layer 204. A first transistor 106 may be formed in the first IC component described in FIG. 1 and a second transistor 206 may be formed in the second IC component described in FIG. 1. As described in FIG. 1, the first transistor 106 may be configured as a common source transistor while the second transistor 206 may be configured as a common gate transistor, or alternatively, the first transistor 106 may be configured as a common gate transistor while the second transistor 206 may be configured as a common source transistor. It should be noted that other device structures may be formed in the respective IC components described in FIG. 1. Examples of other device structures that can be used include, but are not limited to, memory structures (e.g., resistive random memory structures, magnetic random memory structures, etc.), capacitors, or resistors.

As shown in FIG. 2A and FIG. 2B, the first transistor 106 may be formed on the first semiconductor layer 104 in the first semiconductor die 102 and the second transistor 206 may be formed on the second semiconductor layer 204 in the second semiconductor die 202. The inductor structure 282 may be positioned vertically between the first transistor 106 and the second transistor 206. In some embodiments, the first semiconductor die 102 may have a first substrate 103 and the second semiconductor die 202 may have a second substrate 203. Prior to the bonding of the first semiconductor die 102 and the second semiconductor die 202, the second semiconductor die 202 may be in an orientation where the second substrate 203 is below the second transistor 206. As shown in FIG. 2A and FIG. 2B, the second semiconductor die 202 may be flipped or oriented in a manner such that the second substrate 203 is above the second transistor 206. In some embodiments, the first semiconductor layer 104 may be formed over the first substrate 103 in the first semiconductor die 102 and the second semiconductor layer 204 may be formed over the second substrate 203 in the second semiconductor die 202 (before orienting the second semiconductor die 202 in the manner illustrated in FIG. 2A and FIG. 2B). In other embodiments (not shown), the second semiconductor die 202 may not have a second substrate 203 and the second semiconductor layer 204 may be formed over an insulating layer (e.g., a buried oxide layer). Exemplary types of transistors for the first and second transistors 106, 206 may include field effect transistors, bipolar junction transistors, heterojunction bipolar transistors, etc.

Each of the first and second transistors 106, 206 may have input/output regions 108, 110, 208, 210 (e.g., source/drain or emitter/collector) formed in the respective semiconductor layers 104, 204 and a control structure 112, 212 (e.g., base or gate) formed over the respective semiconductor layers 104, 204 and being laterally between the respective input/output regions 108, 110, 208, 210. In some embodiments, the first transistor 106 may have source/drain regions 108, 110 and a gate structure 112. The second transistor 206 may have source/drain regions 208, 210 and a gate structure 212. In other embodiments (not shown), the first transistor 106 may be a field effect transistor while the second transistor 206 may be a heterojunction bipolar transistor.

The first semiconductor die 102 may have an interconnection region 144 formed above the first semiconductor layer 104. Likewise, the second semiconductor die 202 may have an interconnection region 244 formed above the second semiconductor layer 204 (before orienting the second semiconductor die 202 in the manner illustrated in FIG. 2A and FIG. 2B). The interconnection regions 144, 244 may each include one or more interconnection levels formed by a BEOL processing of an integrated circuit (IC) chip. For example, an “n” number of interconnection levels in either of the interconnection regions 144, 244 may be formed in the semiconductor device. The number of interconnection levels may depend on, for example, design requirements or the process involved. As shown in FIG. 2A and FIG. 2B, the interconnection regions 144, 244 may include various interconnect structures. In an implementation, the interconnection region 144 in the first semiconductor die 102 may include contact structures 130, 131, 132, conductive lines 114, 116, 118, 120, 122, and via structures 133, 134, 135. The interconnection region 144 in the second semiconductor die 202 may include contact structures 230, 231, 232, conductive lines 214, 216, 218, 220, 222, and via structures 233, 234, 235.

The contact structures 130, 131, 230, 231 may contact the input/output regions 108, 110 of the respective first and second transistors 106, 206 and provide electrical connection to conductive lines 114, 116, 214, 216. The contact structures 132, 232 may contact the respective control structures 112, 212 and provide an electrical connection to conductive lines 122, 222. The conductive lines 114, 116, 118, 120, 122, 214, 216, 218, 220, 222 may provide routing or wiring of electrical signals to/from other device components in the semiconductor device 100. Conductive lines 114, 116 may be located in a different interconnection level from conductive lines 118, 120. Conductive lines 214, 216 may be located in a different interconnection level from conductive lines 218, 220. The via structures 133, 134, 233, 234 may provide electrical connections between the conductive lines in the different interconnection levels within the interconnection regions 144, 244 (e.g., between conductive lines 118, 120 and conductive lines 114, 116).

The inductor structure 282 may have a first metal level 140 and a second metal level 142 above the first metal level 140. The first metal level 140 may be electrically connected to the first transistor 106. As shown in FIG. 2A and FIG. 2B, an example of the electrical connection between the first metal level 140 and the first transistor 106 may be achieved, for example, by having the via structure 135 contact the first metal level 140 and an interconnect structure in the interconnection region 144, for example, the conductive line 118, which is in turn electrically connected to one of the input/output region 108 of the first transistor through the other interconnect structures in the interconnection region 144, as described herein. Similarly, the second metal level 142 may be electrically connected to the second transistor 206, for example, by having the via structure 235 contact the second metal level 142 and an interconnect structure in the interconnection region 244, for example, the conductive line 220. The conductive line 220 may be electrically connected to one of the input/output regions 210 of the second transistor 206 through the other interconnect structures in the interconnection region 244, as described herein.

A dielectric region 280 may be formed vertically between the first metal level 140 of the inductor structure 282 and the second metal level 142 of the inductor structure 282. The dielectric region 280 may include a first interlayer dielectric level 148 and a second interlayer dielectric level 248 directly on the first interlayer dielectric level 148. The first interlayer dielectric level 148 may have a thickness 148t defined as a vertical distance between its uppermost surface and its lowermost surface. The second interlayer dielectric level 248 may have a thickness 248t defined as a vertical distance between its uppermost surface and its lowermost surface. The thickness 148t of the first interlayer dielectric level 148 may be different from the thickness 248t of the second interlayer dielectric level 248. The interlayer dielectric levels 148, 248 may include, but are not limited to, silicon dioxide, tetraethyl orthosilicate (TEOS), or a material having a chemical composition of SiₓCO_{y}H_{z}, wherein x, y, and z are in stoichiometric ratio. The first interlayer dielectric level 148 may be bonded to the second interlayer dielectric level 248. A bonding interface 150 may be formed vertically between the first interlayer dielectric level 148 and the second interlayer dielectric level 248. The bonding interface 150 may have covalent bonds between the material in the first interlayer dielectric level 148 and the material in the second interlayer dielectric level 248.

As shown in FIG. 2B, the first metal level 140 of the inductor structure 282 may be electrically connected to the second metal level 142 of the inductor structure 282 by a first interconnect via 152 and a second interconnect via 252. The second interconnect via 252 may directly contact the first interconnect via 152. The first interconnect via 152 may be bonded to the second interconnect via 252. The contacting surfaces between the first interconnect via 152 and the second interconnect via 252 may have metallic bonding. The interconnect vias 152, 252 may be arranged vertically between the first metal level 140 and the second metal level 142. The first interconnect via 152 may directly contact the first metal level 140 while the second interconnect via 252 may directly contact the second metal level 142. The interconnect vias 152, 252 may be formed in the dielectric region 280. For example, the first interconnect via 152 may be formed in the first interlayer dielectric level 148 while the second interconnect via 252 may be formed in the second interlayer dielectric level 248. The first interconnect via 152 may have a height 152t defined as a vertical distance between its uppermost surface and its lowermost surface. The second interconnect via 252 may have a height 252t defined as a vertical distance between its uppermost surface and its lowermost surface. The height 152t of the first interconnect via 152 may be different from the height 252t of the second interconnect via 252.

Advantageously, the difference in the thicknesses 148t, 248t of the first and second interlayer dielectric levels 148, 248 or the difference in the heights 152t, 252t of the interconnect vias 152, 252 can enable the control of an inductance parameter between the first metal level 140 of the inductor structure 282 and the second metal level 142 of the inductor structure 282 whilst allowing flexibility in the manufacture of two semiconductor wafers or dies prior to the bonding of the two wafers or dies. For example, the first interlayer dielectric level 148 and the first interconnect via 152 can be formed in a first wafer (or die) while the second interlayer dielectric level 248 and the second interconnect via 252 can be formed in a second wafer (or die), and the respective thickness of the first and second interlayer dielectric levels can be controlled and adjusted in the two separate wafers to correspond with a desired inductance value before directly bonding the first wafer with the second wafer (or the first die with the second die).

Also advantageously, by directly contacting the first and second interconnect vias 152, 252 with each other and directly contacting the interconnect vias 152, 252 with the respective first and second metal levels 140, 142 of the inductor structure 282, the inductance between the first metal level and the second metal level can be controlled by only the heights 152t, 252t of the interconnect vias 152, 252 and the thicknesses 148t, 248t of the interlayer dielectric levels 148, 248.

As shown in FIG. 2B, a first plurality of transistors 106 may be formed on the first semiconductor layer 104. Each transistor 106 in the first plurality of transistors has a gate structure 112. The gate structure of each transistor 106 may be connected to the same conductive line 122. For example, a contact structure 132 may be formed on the gate structure 112 of each transistor 106 in the first plurality of transistors. The contact structure 132 may contact both the gate structure 112 and the conductive line 122.

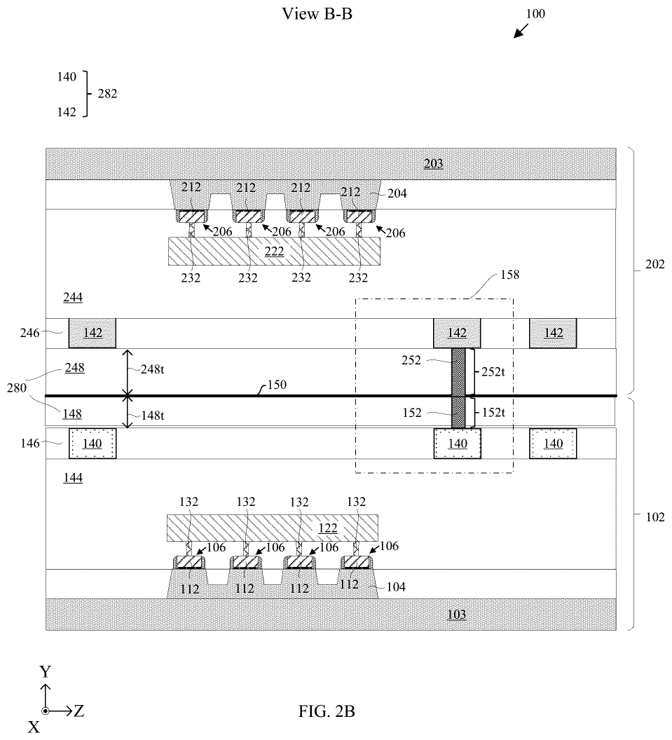

FIG. 3A and FIG. 3B illustrate enlarged cross-sectional views of a region 158 demarcated by broken lines shown in FIG. 2B. Referring to FIG. 3A and FIG. 3B, the first interconnect via 152 may be formed with sidewalls 152a and the second interconnect via 252 may be formed with sidewalls 252a. In the example shown in FIG. 3A, the sidewalls 152a of the first interconnect via 152 may be horizontally offset relative to the sidewalls 252a of the second interconnect via 252 by an offset displacement 1540. Alternatively, in the example shown in FIG. 3B, the sidewalls 152a of the first interconnect via 152 may be aligned vertically with the sidewalls 252a of the second interconnect via 252 (i.e., there is no horizontal offset between the sidewalls 152a, 252a).

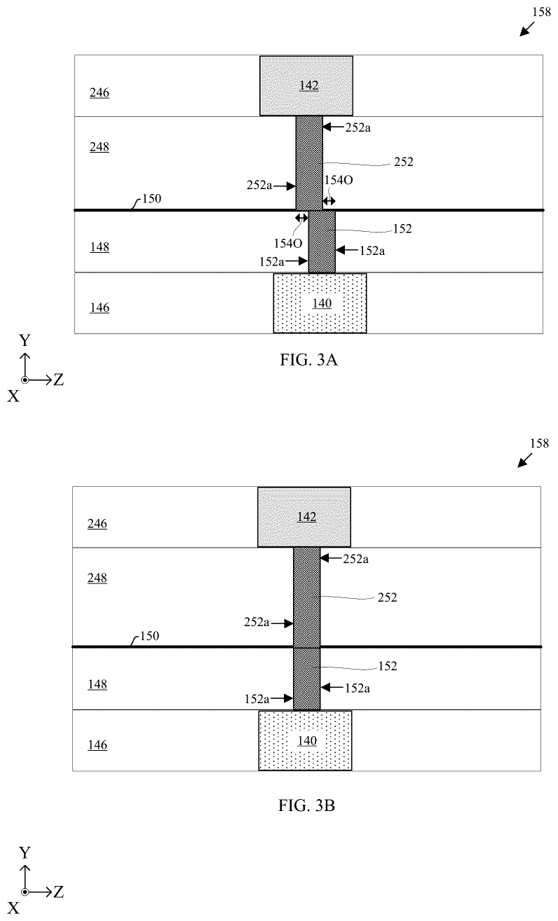

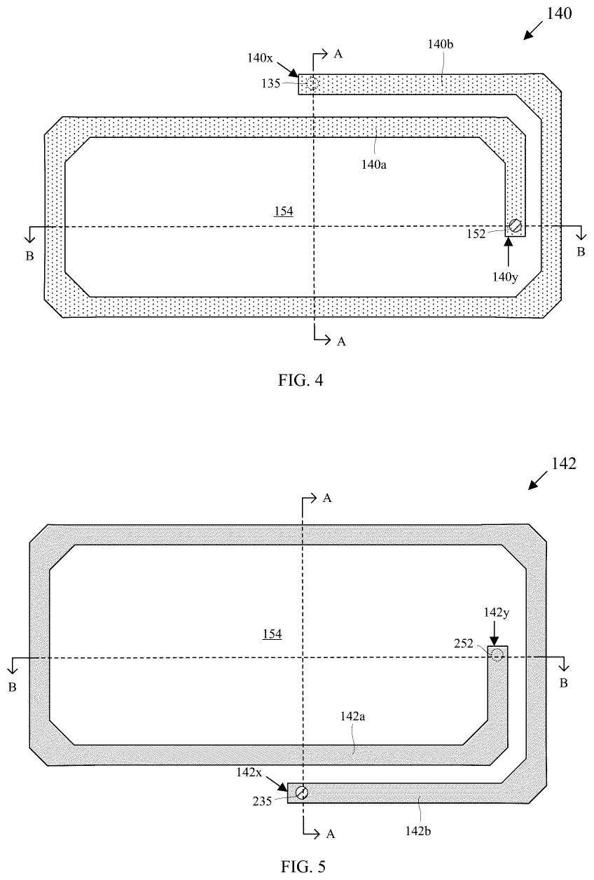

FIG. 4 and FIG. 5 illustrate the top down views of the first metal level 140 of the inductor structure 282 and the second metal level 142 of the inductor structure 282, respectively. The view in FIG. 2A corresponds to a cross-section taken along the line AA in FIG. 4 and FIG. 5 and the view in FIG. 2B corresponds to a cross-section taken along the line BB in FIG. 4 and FIG. 5.

Referring to FIG. 4 and FIG. 5 together with FIG. 2A and FIG. 2B, the inductor structure 282 may have a center region 154. As described herein, the first metal level 140 may include turns 140a, 140b and the second metal level 142 may include turns 142a, 142b. The turns 140a, 140b in the first metal level 140 and the turns 142a, 142b in the second metal level 142 may spiral about the center region 154. The turns 140a, 140b in the first metal level 140 and the turns 142a, 142b in the second metal level 142 may be concentric to the center region 154. The turns 140a, 140b in the first metal level 140 and the turns 142a, 142b in the second metal level 142 may provide spiral paths for which electrical current may flow.

The first metal level 140 may have an innermost end 140y and an outermost end 140x, in which the innermost end 140y may be closer to the center region 154 as compared to the outermost end 140x. The turns 140a, 140b in the first metal level 140 may spiral towards the center region 154 from the outermost end 140x to the innermost end 140y. The via structure 135 may contact the first metal level 140 at the outermost end 140x while the first interconnect via 152 may contact the first metal level 140 at the innermost end 140y. Similarly, the second metal level 142 may have an innermost end 142y and an outermost end 142x, in which the innermost end 142y may be closer to the center region 154 as compared to the outermost end 142x. The turns 142a, 142b in the second metal level 142 may spiral towards the center region 154 from the outermost end 142x to the innermost end 142y. The via structure 235 may contact the second metal level 142 at the outermost end 142x while the second interconnect via 252 may contact the second metal level 142 at the innermost end 142y.

As shown, the turns 140a, 140b in the first metal level 140 and the turns 142a, 142b in the second metal level 142 may form a rectangular shape. Apart from the shape and architecture shown in FIG. 4 and FIG. 5, other shapes and architecture of the metal levels 140, 142 are contemplated. For example, the metal levels 140, 142 may have a polygonal shape with “x” number of sides, in which “x” is an integer. For example, where “x” is zero, the metal levels 140, 142 may have an elliptical, circular, or oval shape. Where “x” is eight, the metal levels 140, 142 may have an octagonal shape. Although not shown, the number of sides of the first metal level 140, 142 may be different from the number of sides of the second metal level 142.

As described herein, the first transistor 106, the second transistor 206, the first metal level 140 of the inductor structure 282, and the second metal level 142 of the inductor structure 282 may be arranged in a vertical stack configuration. In some embodiments, the gate structure 112 of the first transistor 106 may be vertically aligned above the gate structure 212 of the second transistor 206. The first metal level 140 of the inductor structure 282 may be vertically aligned above the second metal level 142 of the inductor structure 282 such that there is overlap between the turns 140a, 140b in the first metal level 140 and the turns 142a, 142b in the second metal level 142. The gate structure 112 of the first transistor 106 and the gate structure 212 of the second transistor 206 may be vertically aligned with the center region 154 of the inductor structure 282. Advantageously, the vertical alignment of the gate structures 112, 212 with the center region 154 of the inductor structure 282 may reduce the footprint or area occupied by the semiconductor device 100 on a printed circuit board as compared to having the inductor structure positioned laterally between two transistors.

The inductor structure 282 may be constructed using various interconnect features to form the turns 140a, 140b, 142a, 142b in the respective metal levels 140, 142. The term “interconnect features” may refer to wiring structures or conductors used in semiconductor devices for enabling transmission of electrical signals between circuitry components within the semiconductor devices. Examples of interconnect features may include, but are not limited to, interconnect vias, interconnect layers, conductive layers, conductive pads, and bond pads. These interconnect features may be formed in a number of ways using a number of different tools. For example, the fabrication of the interconnect features may use at least three building blocks: (i) deposition of material layers over a substrate or a semiconductor chip using deposition techniques, (ii) patterning the deposited material layers to form openings or trenches in the deposited layers using patterning techniques, and (iii) depositing conductive materials into the openings or trenches using deposition techniques.

As used herein, “deposition techniques” refer to the process of applying a material over another material (or the substrate). Exemplary techniques for deposition include, but are not limited to, spin-on coating, sputtering, chemical vapor deposition (CVD), physical vapor deposition (PVD), molecular beam deposition (MBD), pulsed laser deposition (PLD), liquid source misted chemical deposition (LSMCD), atomic layer deposition (ALD).

Additionally, “patterning techniques” include deposition of material or photoresist, patterning, exposure, development, etching, cleaning, and/or removal of the material or photoresist as required in forming a described pattern, structure, or opening. Examples of techniques for patterning include, but are not limited to, wet etch lithographic processes, dry etch lithographic processes, or direct patterning processes. Such techniques may use mask sets and mask layers.

With reference to FIG. 2A and FIG. 2B, an example of forming the semiconductor device 100 may include forming the conductive lines 114, 116, 118, 120 and the interconnection region 144 in a first wafer, and forming the conductive lines 214, 216, 218, 220 and the interconnection region 244 in a second wafer. Formation of the conductive lines 114, 116, 118, 120, 214, 216, 218, 220 and the interconnection regions 144, 244 may utilize the at least three building blocks, as described above.

A dielectric layer 146 may be formed on the interconnection region 144 in the first wafer and a dielectric layer 246 may be formed on the interconnection region 244 in the second wafer. Deposition techniques described herein may be used to form the dielectric layers 146, 246. The dielectric layers 146, 246 may be patterned using patterning techniques to form openings or trenches in the dielectric layers 146, 246, and metals may be deposited into the openings or trenches using deposition techniques to form the first metal level 140 and the second metal level 142.

The first interlayer dielectric level 148 may be formed in the first wafer by depositing a material on the dielectric layer 146 and the first metal level 140. Likewise, the second interlayer dielectric level 248 may be formed in the second wafer by depositing a material on the dielectric layer 246 and the second metal level 142. The first and second interlayer dielectric levels 148, 248 may be patterned to form openings. The openings in the respective first and second wafers may be subsequently filled using deposition techniques to form the first interconnect via 152 and the second interconnect via 252.

The via structures 133, 134, 135, 233, 234, 235, the contact structures 130, 131, 132, 230, 231, 232, the conductive lines 114, 116, 118, 120, 122, 214, 216, 218, 220, 222, and the at least one turn in the respective first and second metal levels 140, 142 may include a metal, such as tantalum (Ta), tungsten (W), ruthenium (Ru), cobalt (Co), copper (Cu), titanium (Ti), nickel (Ni), platinum (Pt), aluminum (Al), or an alloy thereof. Other suitable types of metal, alloys, or conductive materials may also be useful. The via structures 133-135, 233-235, the contact structures 130-132, 230-232, the conductive lines 114, 116, 118, 120, 122, 214, 216, 218, 220, 222, and the at least one turn in the respective first and second metal levels 140, 142 may be formed using a damascene process (e.g., a single damascene or a dual damascene). Other techniques, such as reactive ion etch (RIE) may also be used in the formation of the via structures 133-135, 233-235, the contact structures 130-132, 230-232, the conductive lines 114, 116, 118, 120, 122, 214, 216, 218, 220, 222, and the at least one turn in the respective first and second metal levels 140, 142.

The second wafer may be aligned vertically above the first wafer such that the second interconnect via 252 may be aligned vertically above the first interconnect via 152. The first wafer may be bonded to the second wafer by directly contacting the two wafers such that the first interlayer dielectric level 148 contacts the second interlayer dielectric level 248 and the first interconnect via 152 contacts the second interconnect via 252. An anneal process or heat treatment process may be applied to the two wafers that are in contact with each other to bond the first and second interlayer dielectric levels 148, 248 together and the first and second interconnect vias 152, 252 together. As mentioned above, the bonded wafer may be diced to form the semiconductor device 100.

In embodiments where the inductor structure has more than one metal level in the first semiconductor die 102, the second semiconductor die 202, or both semiconductor dies 102, 202, the conductive lines 114, 116, 118, 120 in the interconnection region 144 of the first semiconductor die 102 and the conductive lines 214, 216, 218, 220 in the interconnection region 244 of the second semiconductor die 202 may be used for constructing metal levels of the inductor structure 282, as well as structural features for the transmission of electrical signals between the transistors 106, 206 and other circuitry components in the semiconductor device 100.

Throughout this disclosure, it is to be understood that if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in an embodiment” herein do not necessarily all refer to the same embodiment.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. Furthermore, there is no intention to be bound by any theory presented in the preceding background or the following detailed description. Additionally, the various tasks and processes described herein may be incorporated into a more comprehensive procedure or process having additional functionality not described in detail herein.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate +/−10% of the stated value(s).

As will be readily apparent to those skilled in the art upon a complete reading of the present application, the disclosed semiconductor devices and methods of forming the same may be employed in manufacturing a variety of different integrated circuit products, including, but not limited to, radio frequency (RF) modules or applications, FinFET devices, planar transistor devices, CMOS devices, wide bandgap semiconductor devices, etc.

What is claimed is:

1. A semiconductor device comprising:
a first semiconductor layer;
a second semiconductor layer;
an inductor structure vertically between the first semiconductor layer and the second semiconductor layer, the inductor structure having a first metal level and a second metal level above the first metal level, the first metal level and the second metal level each comprises at least one turn about a vertical axis;
a dielectric region vertically between the first and second metal levels of the inductor structure;
a first interconnect via in the dielectric region, the first interconnect via has a height, and the first interconnect via electrically contacts the first metal level of the inductor structure; and
a second interconnect via in the dielectric region, the second interconnect via directly contacts the first interconnect via, the second interconnect via has a height different from the height of the first interconnect via, and the second interconnect via electrically contacts the second metal level of the inductor structure.

2. The semiconductor device of claim 1, wherein the dielectric region includes a first interlayer dielectric level and a second interlayer dielectric level directly on the first interlayer dielectric level, the second interlayer dielectric level has a different thickness from the first interlayer dielectric level.

3. The semiconductor device of claim 2, wherein the first interconnect via is in the first interlayer dielectric level and the second interconnect via is in the second interlayer dielectric level.

4. The semiconductor device of claim 3, wherein the first interconnect via has sidewalls, the second interconnect via has sidewalls, and the sidewalls of the first interconnect via are horizontally offset relative to the sidewalls of the second interconnect via.

5. The semiconductor device of claim 3, wherein the first interconnect via has sidewalls, the second interconnect via has sidewalls, and the sidewalls of the first interconnect via are aligned vertically with the sidewalls of the second interconnect via.

6. The semiconductor device of claim 3, further comprising:
a first transistor on the first semiconductor layer, wherein the first metal level of the inductor structure is electrically connected to the first transistor; and
a second transistor on the second semiconductor layer, wherein the second metal level of the inductor structure is electrically connected to the second transistor.

7. The semiconductor device of claim 6, further comprising:
a first semiconductor die including the first interlayer dielectric level, the first transistor, the first semiconductor layer, the first metal level of the inductor structure, and the first interconnect via; and
a second semiconductor die including the second interlayer dielectric level, the second transistor, the second semiconductor layer, the second metal level of the inductor structure, and the second interconnect via.

8. The semiconductor device of claim 7, wherein the first interlayer dielectric level is bonded to the second interlayer dielectric level and the first interconnect via is bonded to the second interconnect via.

9. The semiconductor device of claim 6, wherein the first transistor has a gate structure, the second transistor has a gate structure, and the gate structure of the first transistor is vertically aligned above the gate structure of the second transistor.

10. The semiconductor device of claim 9, wherein the inductor structure has a center region, and wherein the gate structure of the first transistor and the gate structure of the second transistor are vertically aligned with the center region of the inductor structure.

11. A semiconductor device comprising:
a first transistor on a first semiconductor layer, the first transistor has a gate structure;
a second transistor on a second semiconductor layer, the second transistor has a gate structure;
an inductor structure vertically between the first transistor and the second transistor, the inductor structure having a center region, a first metal level, and a second metal level above the first metal level, the first metal level is electrically connected to the first transistor, the second metal level is electrically connected to the second transistor, the first metal level and the second metal level each comprises at least one turn that spiral about the center region of the inductor structure, wherein the gate structure of the first transistor and the gate structure of the second transistor are vertically aligned with the center region of the inductor structure;
a dielectric region vertically between the first and second metal levels of the inductor structure;
a first interconnect via in the dielectric region, the first interconnect via electrically contacts the first metal level of the inductor structure; and
a second interconnect via in the dielectric region, the second interconnect via directly contacts the first interconnect via, and the second interconnect via electrically contacts the second metal level of the inductor structure.

12. A semiconductor device comprising:
a first semiconductor die having a first interlayer dielectric level;
a first integrated circuit (IC) component in the first semiconductor die;
a second semiconductor die vertically above the first semiconductor die, the second semiconductor die having a second interlayer dielectric level, the second interlayer dielectric level directly contacts the first interlayer dielectric level, and the second interlayer dielectric level has a different thickness from the first interlayer dielectric level;
a second IC component in the second semiconductor die;
an inductor structure vertically between the first IC component and the second IC component, the inductor structure having a first metal level in the first semiconductor die and a second metal level in the second semiconductor die, the first metal level is electrically connected to the first IC component, and the second metal level is electrically connected to the second IC component, the first metal level and the second metal level each comprises at least one turn about a vertical axis;
a first interconnect via in the first interlayer dielectric level, the first interconnect via electrically contacts the first metal level of the inductor structure; and
a second interconnect via in the second interlayer dielectric level, the second interconnect via directly contacts the first interconnect via, and the second interconnect via electrically contacts the second metal level of the inductor structure.

13. The semiconductor device of claim 12, wherein the first interconnect via, the second interconnect via, the first interlayer dielectric level, and the second interlayer dielectric level are vertically between the first metal level of the inductor structure and the second metal level of the inductor structure.

14. The semiconductor device of claim 13, wherein the first interconnect via has sidewalls, the second interconnect via has sidewalls, and the sidewalls of the first interconnect via are horizontally offset relative to the sidewalls of the second interconnect via.

15. The semiconductor device of claim 13, wherein the first interconnect via has sidewalls, the second interconnect via has sidewalls, and the sidewalls of the first interconnect via are aligned vertically with the sidewalls of the second interconnect via.

16. The semiconductor device of claim 12, wherein the inductor structure has a center region, and wherein the at least one turn in the first metal level and the at least one turn in the second metal level spiral about the center region of the inductor structure.

17. The semiconductor device of claim 12, wherein the first IC component includes a first transistor connected to the first metal level of the inductor structure, and the second IC component includes a second transistor connected to the second metal level of the inductor structure.

18. The semiconductor device of claim 17, wherein the first transistor is a field effect transistor and the second transistor is a bipolar junction transistor.

19. The semiconductor device of claim 12, wherein the first IC component, the second IC component, the first metal level of the inductor structure, and the second metal level of the inductor structure are aligned vertically along the vertical axis.

20. The semiconductor device of claim 12, wherein the second interconnect via has a height different from the height of the first interconnect via.
